(19) United States
(12) Patent Application Publication
(10) Pub. No.: US 2026/0084641 A1
(43) Pub. Date: Mar. 26, 2026

(54) SAFETY DEVICE TEST SYSTEM FOR A VEHICLE

(71) Applicant: NISSAN NORTH AMERICA, INC., Franklin, TN (US)

(72) Inventor: Christopher Edward SCHMIDT, Rochester, MI (US)

(21) Appl. No.: 18/893,705

(22) Filed: Sep. 23, 2024

(51) Int. Cl. B60R 21/017; G01R 31/54

(52) U.S. Cl. CPC B60R 21/0173; G01R 31/54

(57) ABSTRACT

A vehicle safety device test system includes a vehicle, a first safety device, an electronic controller, a breakout box, and a data acquisition system. The first safety device is disposed in the vehicle. The electronic controller is disposed in the vehicle. The electronic controller is electrically connected to the first safety device. The breakout box is disposed in the vehicle. The breakout box is electrically connected to the electronic controller. The data acquisition system is disposed in the vehicle. The data acquisition system is electrically connected to the breakout box.

### BACKGROUND

### Technical Field

The present disclosure generally relates to a safety device test system for a vehicle. More specifically, the present disclosure relates to a safety device test system for a vehicle in which a breakout box is electrically connected to an electronic controller.

### Background Information

A safety device, such as an airbag, test system for a vehicle requires extensive wiring to be installed in a vehicle prior to conducting a test of the vehicle safety device system. The extensive wiring required increases the possibility of miswiring. Wiring can be improperly installed, which can negatively impact deployment of an airbag. These errors can invalidate the airbag system test, which is expensive to conduct. The extensive wiring also requires a large amount of time to install, which further increases the possibility of a wiring error during installation.

### SUMMARY

A need exists for an improved safety device test system for a vehicle.

In view of the state of the known technology, one aspect of the present disclosure is to provide a vehicle airbag test system including a vehicle, a first airbag, an electronic controller, a breakout box, and a data acquisition system. The first airbag is disposed in the vehicle. The electronic controller is disposed in the vehicle. The electronic controller is electrically connected to the first airbag. The breakout box is disposed in the vehicle. The breakout box is electrically connected to the electronic controller. The data acquisition system is disposed in the vehicle. The data acquisition system is electrically connected to the breakout box.

Another aspect of the present disclosure is to provide a vehicle safety device test system for a vehicle. The vehicle safety device test system includes a vehicle, a breakout box disposed in the vehicle, an electronic controller disposed in the vehicle, and a vehicle wiring harness disposed in the vehicle. An electrical connector is connected to the vehicle wiring harness. A first test assembly harness electrically connects the breakout box and the electronic controller. A second test assembly harness electrically connects the breakout box and the electrical connector.

Also other objects, features, aspects and advantages of the disclosed safety device test system for a vehicle will become apparent to those skilled in the art from the following detailed description, which, taken in conjunction with the annexed drawings, discloses exemplary embodiments of the safety device test system for a vehicle.

### BRIEF DESCRIPTION OF THE DRAWINGS

Referring now to the attached drawings which form a part of this original disclosure:

FIG. 1 is a schematic illustration of the vehicle safety device test system disposed in a vehicle;

FIG. 2 is a schematic illustration of an electrical path of the vehicle safety device test system of FIG. 1; and

FIG. 3 is an electrical schematic of the vehicle safety device test system of FIG. 1.

### DETAILED DESCRIPTION OF EMBODIMENTS

Selected embodiments will now be explained with reference to the drawings. It will be apparent to those skilled in the art from this disclosure that the following descriptions of the embodiments are provided for illustration only and not for the purpose of limiting the invention as defined by the appended claims and their equivalents.

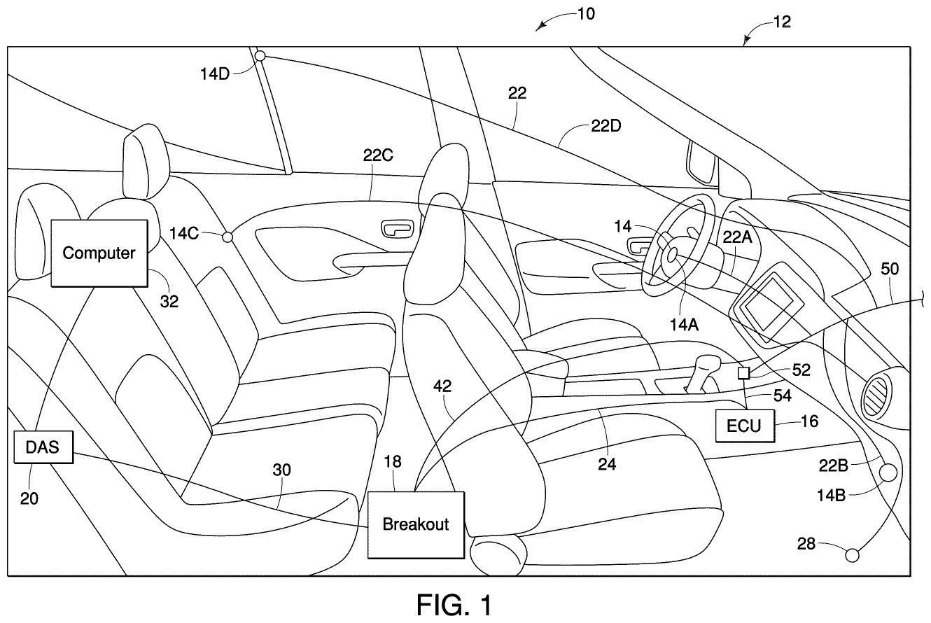

Referring initially to FIG. 1, a vehicle safety device test system 10 in accordance with an exemplary embodiment is disposed in a vehicle 12. The safety device test system 10 further includes at least one safety device, such as airbag 14, an electronic controller 16, a breakout box 18, and a data acquisition system (DAS) 20. Although the safety device test system 10 is described as an airbag test system, the test system can be for any vehicle safety device. The vehicle safety device can be, but is not limited to, a supplemental restraint system (SRS), or airbag, a pyrotechnic device, a safety device, a passive safety device, a relay device, a retractor, and an anchor pretensioner.

A plurality of safety devices, such as airbags 14, are disposed in the vehicle 10, as shown in FIG. 1. The airbags 14 can be disposed in any suitable location, such as a driver airbag 14A, a passenger airbag 14B, a side airbag 14C, and a curtain airbag 14D. The plurality of airbags 14 are conventional airbags.

The electronic controller 16 is disposed in the vehicle 12, as shown in FIG. 1. The electronic controller 16 is a safety device control unit, such as an airbag control unit, configured to control the plurality of safety devices, such as the airbags 14.

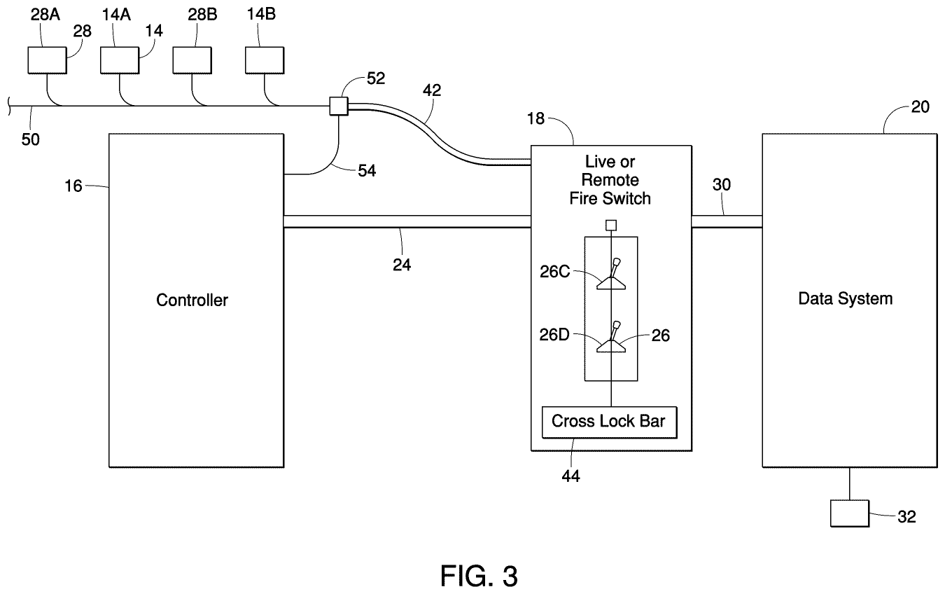

Each airbag 14, or safety device, is connected to the electronic controller 16, as shown in FIGS. 1 and 3. An electrical wire 22 of a vehicle wiring harness 50 connects each airbag 14 to an electrical connector 52. The electrical connector 52 is directly electrically connected to the breakout box 18 through a second wiring, or test assembly, harness 42. The breakout box 18 is directly electrically connected to the electronic controller 16 by a first wiring, or test assembly, harness 24. In other words, the electronic controller 16 is electrically connected to each airbag 14. The driver airbag 14A is connected to the electrical connector 52 by a first electrical wire 22A of the vehicle wiring harness 50. The passenger airbag 14B is connected to the electrical connector 52 by a second electrical wire 22B of the vehicle wiring harness 50. The side airbag 14C is connected to the electrical connector 52 by a third electrical wire 22C of the vehicle wiring harness 50. The curtain airbag 14D is connected to the electrical connector 52 by a fourth electrical wire 22A of the vehicle wiring harness 50. The electrical connector 52 is directly electrically connected to the breakout box 18 by the second wiring, or test assembly, harness 42. The electrical connector 52 is directly electrically connected to the electronic controller 16 by the electrical cable 54.

The first wiring, or test assembly, harness 24 is directly electrically connected between the electronic controller 16 and the breakout box 18, as shown in FIG. 1. The second wiring, or test assembly, harness 42 is directly electrically connected between the breakout box 18, which is electrically connected to the electronic controller 16 by the first wiring harness 24, and the electrical connector 52. Each safety device 14 and sensor 28 is connected to the electrical connector 52 through the vehicle wiring harness 50, such that each airbag 14, or safety device, is electrically connected to the electronic controller 16.

The electrical connector 52 is connected to the vehicle wiring harness 50, as shown in FIGS. 1 and 3. The vehicle wiring harness 50 is electrically connected to each of the safety devices 14 and each of the vehicle sensors 28. The second wiring harness 42 is connected between the electrical connector 52 and the breakout box 18. An electrical cable 54, such as a jumper, electrically connects the electronic controller 16 and the electrical connector 52.

The electronic controller 16 is configured to control deployment of the plurality of airbags 14 responsive to signals received from vehicle sensors 28. The vehicle sensors 28 are disposed in conventional locations in the vehicle 12. When a signal is received from a vehicle sensor 28 that exceeds a predetermined threshold, the electronic controller 16 transmits a signal to activate the appropriate airbag 14. The electronic controller 16 is programmed to deploy the appropriate airbag 14 responsive to the signal received from the vehicle sensors 28. During an airbag safety test, the sensor 28 transmits the signal through the vehicle wiring harness 50 to the electrical connector 52, to the electronic controller 16 through the electrical cable 54, to the breakout box 18 through the first wiring harness 24, to the electrical connector 52 through the through the second wiring harness 42, and to the airbag 14 through the vehicle wiring harness 50. The signal received by the airbag 14 activates an inflator within the airbag 14 to cause the airbag 14 to deploy. For other safety device tests, the electronic controller 16 is configured to operate or activate, as applicable, the safety device being tested.

The electronic controller 16 preferably includes a microcomputer that communicates with the various vehicle sensors 28, as shown in FIG. 3. The electronic controller 16 can also include other conventional components, such as an input interface circuit, an output interface circuit, and storage devices, such as a ROM (Read Only Memory) device and a RAM (Random Access Memory) device and electronic storage devices or drives (all hereinafter referred to collectively as electronic memory). The microcomputer of the electronic controller 16 is programmed to control the vehicle airbag test system 10. The memory circuit stores processing results and control programs, such as ones for the vehicle airbag test system 10 that are run by the processor circuit. The electronic controller 16 is operatively coupled to the various vehicle components and components of the vehicle airbag test system 10 in a conventional manner. The internal RAM of the electronic controller 16 stores statuses of operational flags and various control data. The internal ROM of the electronic controller 16 stores data communication protocols and commands for various operations. The electronic controller 16 is capable of selectively controlling any of the components of the control system of the vehicle airbag test system 10 in accordance with the control program. It will be apparent to those skilled in the art from this disclosure that the precise structure and algorithms for the electronic controller 16 can be any combination of hardware and software that will carry out the functions of the vehicle airbag test system 10.

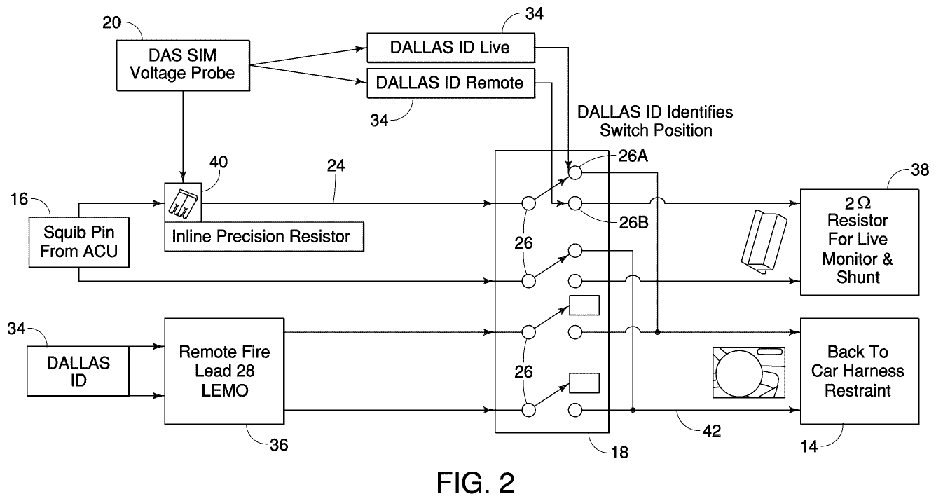

The breakout box 18 is disposed in the vehicle 12, as shown in FIG. 1. The breakout box 18 is electrically connected to the electronic controller 16. The first wiring harness 24 electrically connects the breakout box 18 and the electronic controller 16, as shown in FIGS. 1 and 2. The first wiring, or test assembly, harness 24 is directly connected between the breakout box 18 and the electronic controller 16. The breakout box 18 monitors the current in the first wiring harness 24. The signal from the sensor 28 that is configured to activate the airbag 14 passes through the breakout box 18, such that the current can be monitored.

The breakout box 18 includes at least one setting switch 26 configured to be switchable between a first position 26A and a second position 26B, as shown in FIGS. 2 and 3, to control operation of an airbag 14 during an airbag test. As shown in FIG. 2, the breakout box 18 can include a plurality of switches 26. The breakout box 18 preferably includes a switch 26 for each airbag 14 to be tested. The switch 26 being in the first position 26A sets the airbag test to be a live airbag test. The switch 26 being in the second position 26B sets the airbag test to be a remote airbag test. The switch 26 is configured to be manually set in either the first position or the second position. The switch 26 is preferably disposed on an external surface of the breakout box 18 to facilitate access thereto.

When the setting switch 26 is in the first position 26A for the live airbag test, the electronic controller 16 is configured to deploy the airbag 14 when the sensor 28 disposed in the vehicle detects a value that is greater than or equal to a first predetermined value. The live airbag test causes deployment of the airbag 14 responsive to a condition sensed by the vehicle sensor 28.

When the setting switch 26 is in the second position 26B for the remote airbag test, the electronic controller 16 is configured to deploy the airbag 14 when a first predetermined amount of time is exceeded. The first predetermined amount of time is measured from any suitable time, such as a start of the remote airbag test. The remote airbag test causes deployment of the airbag 14 after the predetermined amount of time has passed from the start of the remote airbag test. In other words, the remote airbag test does not deploy the airbag 14 responsive to a sensed condition from the sensors 28. During the remote airbag test, the airbag 14 is deployed responsive to a setting input to the data acquisition system 20, such as a predetermined amount of time from a start of the remote airbag test.

The breakout box 18 includes a lock-out switch 44, as shown in FIG. 2, configured to disconnect power to the electronic controller 16. The lock-out switch 44 is preferably a conventional knife switch. When the lock-out switch 44 is in a closed position, electrical power to the electronic controller 16 is not interrupted. When the lock-out switch 44 is in an open position, power to the electronic controller 16 is disconnected. A conventional knife switch includes a knife hingedly connected to a base, and a jaw for receiving the knife. The jaw receives the knife in the closed position, and the jaw is disengaged from the jaw in the open position. The lock-out switch 44 is configured to remain in the closed position during the airbag test, such that the switch 26 does not move to the open position during the airbag test due to the large gravitational forces generated during the airbag test.

The breakout box 18 further includes a resistor 40, as shown in FIG. 2, configured to monitor a current during the airbag test. The monitored current from the electronic controller 16 to the breakout box 18 can be analyzed and evaluated following the airbag test.

The breakout box 18 further includes a shunting resistor 38 configured to prevent a signal from being sent to an airbag 14 when the switch 26 is set for a remote airbag test. During the remote airbag test, the electronic controller 16 is programmed to transmit a signal to a specified airbag 14 at a specified time. The shunting resistor 38 prevents a firing signal from being transmitted to an airbag 14, through the breakout box 18 from the electronic controller 16, that is not programmed to be deployed during the airbag test responsive to signals transmitted by the sensor 28.

A remote firing cable 36 of the wiring harness 30 is connected between the DAS 20 and the breakout box 18, as shown in FIG. 2. The remote firing cable 36 transmits a signal through the wiring harness 36 to deploy the programmed airbag 14 at the predetermined time during a remote airbag test.

The data acquisition system 20 is disposed in the vehicle 12, as shown in FIG. 1. The DAS is electrically connected to the breakout box 18 by the wiring harness, 30, as shown in FIGS. 2 and 3. The DAS 20 is configured to acquire data prior to, during and after the airbag test. The DAS 20 includes a memory, such as a data logger, configured to record and store data acquired by the DAS 20.

The DAS 20 includes at least one identifier 34, such as a Dallas ID, configured to identify the position of the at least one switch 26, as shown in FIG. 2. The identifier 34 is configured to identify whether the switch 26 is in the first position, i.e., live position, or the second position, i.e., remote position. In other words, the DAS 20 receives and stores a position of the switch 26.

A computer 32 is configured to be electrically connected to the DAS 20 of the airbag test system 10, as shown in FIGS. 1 and 3. The computer 32 is preferably disconnected from the DAS 20, and removed from the vehicle 12 prior to conducting the airbag test. The computer 32 is configured to create a setup file prior to conducting the airbag test, and to download the data stored by the DAS 20 during and after the airbag test. The computer 32 can be used to input to the DAS 20 the predetermined amount of time at which the airbag 14 is to be deployed during the remote airbag test.

To assemble the vehicle safety device test system 10 to conduct a safety device test, the vehicle wiring harness 50 is connected to the electrical connector 52. Initially, the vehicle wiring harness 50 is directly connected to the electronic controller 16. The vehicle wiring harness 50 is disconnected from the electronic controller 16 and connected to the electrical connector 52 to conduct a safety device test. The first wiring harness 24 is electrically connected between the electronic controller 16 and the breakout box 18. A first end of the first wiring harness 24 is electrically connected to the electronic controller 16. A second end of the first wiring harness 24 is electrically connected to the breakout box 18.

The second wiring harness 42 is electrically connected between the breakout box 18 and the electrical connector 52. A first end of the second wiring harness 42 is electrically connected to the breakout box 18. A second end of the second wiring harness 42 is electrically connected to the electrical connector 52.

The electrical cable 54 is electrically connected between the electronic controller 16 and the electrical connector 52. The data acquisition system (DAS) 20 is connected to the breakout box 18 by an electrical cable, or harness, 30, as shown in FIGS. 1 and 3. A computer 32 can be electrically connected to the DAS 20 to input parameters for the vehicle safety device test.

The switch 26 is then set for either a live safety device test or a remote safety device test. The identifier 34 identifies whether the switch 26 is set for a live safety device test or a remote safety device test.

To conduct a live airbag test of the first and second airbags 14A and 14B disposed in the vehicle 12, the first switch 26C and the second switch 26D of the breakout box 18 are set to the first position 26A, as shown in FIG. 1-3. The identifier 34 identifies that the switches 26C and 26DB are set for a live safety device test. When the airbag test is initiated, the electronic controller 16 transmits a signal to each of the first and second airbags 14 based on conditions sensed by the sensors 28A and 28B. The first sensor 28A can detect a condition designed to cause the first airbag 14A to deploy when a value greater than or equal to a first predetermined value is detected. The second sensor 28B can detect a condition designed to cause the second airbag 14B to deploy when a value greater than or equal to a second predetermined value is detected. The electronic controller 16 can be programmed in any suitable manner such that an airbag is deployed based on a condition sensed by one sensor 28 or by a combination of conditions sensed by a plurality of sensors 28.

During the live airbag test, which is based on conditions sensed by the vehicle sensors 28, a signal generated by at least one of the sensors 28 travels from sensor 28 to the electrical connector 52 through the vehicle wiring harness 50, and then to the electronic controller 16 through the electrical cable, or jumper, 54. The electronic controller 16 transmits an appropriate firing signal through the first wiring harness 24 to the breakout box 18. The breakout box 18 then transmits a firing signal through the second wiring harness 42 to the electrical connector 52 and through the vehicle wiring harness 50 to the appropriate airbag 14 to be deployed. The firing signal transmitted from the breakout box 18 to the respective airbag 14 does not pass through the electronic controller 16. The firing signal is also transmitted from the breakout box 18 to the DAS 20. The data logger of the DAS 20 records and stores the transmitted information for analysis and evaluation following the airbag test.

During the live safety device test, an electrical signal is transmitted from the vehicle sensor 28 to the electrical connector 52 through the vehicle wiring harness 50, to the electronic controller 16 through the electrical cable 54, to the breakout box 18 through the first vehicle wiring harness 24, to the electrical connector 52 through the second vehicle wiring harness 42, and to the safety device 14 through the vehicle wiring harness 50, in that order. In other words, the signal transmitted by the breakout box through the second wiring harness 42 does not pass through the electronic controller 16 when transmitting the signal from the breakout box 18 to the safety device 14.

To conduct a remote airbag test of the first and second airbags 14A and 14B disposed in the vehicle 12, the first switch 26C and the second switch 26D of the breakout box 18 are set to the second position 26B, as shown in FIG. 1-3. The identifier 34 identifies that the switches 26C and 26D are set for a remote safety device test. The computer 32 can be connected to the DAS 20 to set which airbags 14 are to be deployed during the remote test, and to set the predetermined amount of time at which the airbag 14 is to be deployed. The electronic controller 16 can be configured such that any number of airbags 14, such as one airbag or multiple airbags, can be deployed during the remote airbag test.

When the remote airbag test is initiated, a signal is transmitted from the DAS 20 through the remote firing cable 36 to the breakout box 18. The breakout box 18 then transmits a signal through the second electrical harness 42 to the electrical connector 52 and through the vehicle wiring harness 50 to each of the first and second airbags 14 to deploy at the predetermined amount of time after the remote airbag test is initiated. The firing signal transmitted from the breakout box 18 to the respective airbag 14 does not pass through the electronic controller 16. The shunting resistor 38 prevents an airbag 14 from being deployed during the remote airbag test based on conditions sensed by the vehicle sensors 28 and transmitted through the electronic controller 16 to the breakout box 18.

During the remote airbag test, a signal generated by the DAS 20 is transmitted to the breakout box 18, to the electrical connector 52 through the second electrical harness 42, and to the respective airbags 14 through the vehicle wiring harness 50. A signal received from the electronic controller 16 responsive to a condition sensed by the sensor 28 is transmitted to the breakout box 18 and monitored. The shunting resistor prevents a firing signal from being transmitted to the airbag 14 based on the condition sensed by the sensor 28. Deployment of an airbag during the remote airbag test is limited to an airbag programmed through the DAS 20 to deploy. The data logger of the DAS 20 records and stores the transmitted information for analysis and evaluation following the remote airbag test.

Although the live and remote safety device tests were describe as testing vehicle airbags, the live and remote safety device tests are equally applicable to any vehicle safety device, such as, but not limited to, a pyrotechnic device, a safety device, a passive safety device, a relay device, a retractor, and an anchor pretensioner.

The safety device test system 10 reduces the installation and preparation time required to conduct a vehicle safety device test, as well as reducing errors arising from installation and preparation by decreasing the complexity of the vehicle safety device test system 10.

### GENERAL INTERPRETATION OF TERMS

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Also as used herein to describe the above embodiment(s), the following directional terms “forward”, “rearward”, “above”, “downward”, “vertical”, “horizontal”, “below” and “transverse” as well as any other similar directional terms refer to those directions of a vehicle equipped with the vehicle safety device test system. Accordingly, these terms, as utilized to describe the present invention should be interpreted relative to a vehicle equipped with the vehicle safety device test system.

The term “detect” as used herein to describe an operation or function carried out by a component, a section, a device or the like includes a component, a section, a device or the like that does not require physical detection, but rather includes determining, measuring, modeling, predicting or computing or the like to carry out the operation or function.

The term “configured” as used herein to describe a component, section or part of a device includes hardware and/or software that is constructed and/or programmed to carry out the desired function.

The terms of degree such as “substantially”, “about” and “approximately” as used herein mean a reasonable amount of deviation of the modified term such that the end result is not significantly changed.

While only selected embodiments have been chosen to illustrate the present invention, it will be apparent to those skilled in the art from this disclosure that various changes and modifications can be made herein without departing from the scope of the invention as defined in the appended claims. For example, the size, shape, location or orientation of the various components can be changed as needed and/or desired. Components that are shown directly connected or contacting each other can have intermediate structures disposed between them. The functions of one element can be performed by two, and vice versa. The structures and functions of one embodiment can be adopted in another embodiment. It is not necessary for all advantages to be present in a particular embodiment at the same time. Every feature which is unique from the prior art, alone or in combination with other features, also should be considered a separate description of further inventions by the applicant, including the structural and/or functional concepts embodied by such feature(s). Thus, the foregoing descriptions of the embodiments according to the present invention are provided for illustration only, and not for the purpose of limiting the invention as defined by the appended claims and their equivalents.

What is claimed is:

1. A vehicle safety device test system comprising:
a vehicle;
a first safety device disposed in the vehicle;
an electronic controller disposed in the vehicle, the electronic controller being electrically connected to the first safety device;
a breakout box disposed in the vehicle, the breakout box being electrically connected to the electronic controller; and
a data acquisition system disposed in the vehicle, the data acquisition system being electrically connected to the breakout box.

2. The vehicle safety device test system according to claim 1, wherein
the breakout box includes a first switch configured to be switchable between a first position and a second position to control operation of the first safety device during a safety device airbag test.

3. The vehicle air safety device bag test system according to claim 2, wherein
the first switch being in the first position sets the safety device test to be a live safety device test.

4. The vehicle safety device test system according to claim 3, wherein
when the first switch is set in the first position for the live safety device test, the electronic controller is configured to activate the first safety device when a first sensor disposed in the vehicle detects a value that is greater than or equal to a first predetermined value.

5. The vehicle safety device test system according to claim 4, wherein
the first switch being in the second position sets the safety device test to be a remote safety device test.

6. The vehicle safety device test system according to claim 5, wherein
when the first switch is in the second position for the remote safety device test, the electronic controller is configured to deploy the first safety device when a first predetermined amount of time is exceeded.

7. The vehicle safety device test system according to claim 6, wherein
the predetermined amount of time is measured from a start of the remote safety device test.

8. The vehicle safety device test system according to claim 7, wherein
the predetermined amount of time is input to the data acquisition system.

9. The vehicle safety device test system according to claim 6, wherein
a second safety device is disposed in the vehicle, the second safety device being electrically connected to the electronic controller; and
the breakout box includes a second switch configured to be switchable between a first position and a second position to control operation of the second safety device during an airbag test.

10. The vehicle safety device test system according to claim 9, wherein
the second switch being in the first position sets the airbag test the live safety device test.

11. The vehicle safety device test system according to claim 10, wherein
when the second switch is set in the first position for the live safety device test, the electronic controller is configured to activate the second safety device when a second sensor disposed in the vehicle detects a value that is greater than or equal to a second predetermined value.

12. The vehicle safety device test system according to claim 11, wherein
the second switch being in the second position sets the safety device test the remote safety device test.

13. The vehicle safety device test system according to claim 12, wherein
when the second switch is set in the second position for the remote safety device test, the electronic controller is configured to activate the second safety device when a second predetermined amount of time is exceeded.

14. The vehicle safety device test system according to claim 13, wherein
a first resistor is configured to prevent the first safety device from deploying during the remote safety device test.

15. The vehicle safety device test system according to claim 13, wherein
the breakout box includes a resistor configured to monitor a current during the safety device test.

16. The vehicle safety device test system according to claim 2, wherein
the data acquisition system receives and stores the position of the first switch.

17. The vehicle safety device test system according to claim 2, wherein
the data acquisition system is configured to determine whether the first switch is in the first position or the second position.

18. A vehicle safety device test system comprising:
a vehicle;
a breakout box disposed in the vehicle;
an electronic controller disposed in the vehicle;
a vehicle wiring harness disposed in the vehicle;
an electrical connector connected to the vehicle wiring harness;
a first test assembly harness electrically connecting the breakout box and the electronic controller; and
a second test assembly harness electrically connecting the breakout box and the electrical connector.

19. The vehicle safety device test system according to claim 18, wherein
the vehicle wiring harness is electrically connected to a safety device and a sensor, the sensor being configured to detect a condition configured to activate the safety device.

20. The vehicle safety device test system according to claim 19, wherein
during a vehicle safety device test, an electrical signal is transmitted from the sensor to the electrical connector through the vehicle wiring harness, to the electronic controller through an electrical cable, to the breakout box through the first test assembly harness, to the electronic controller through the second test assembly harness, and to the safety device through the vehicle wiring harness, in that order.
